(19) United States
(12) Patent Application Publication
(10) Pub. No.: US 2016/0049197 A1
(43) Pub. Date: Feb. 18, 2016

(54) Memory Devices Including a Plurality of Layers and Related Systems

(71) Applicant: Samsung Electronics Co., Ltd., Suwon-si (KR)

(72) Inventors: Hyun-kook PARK, Anyang-si (KR); Yeong-taek LEE, Seoul (KR); Chi-weon YOON, Seoul (KR)

(21) Appl. No.: 14/744,605

(22) Filed: Jun. 19, 2015

(30) Foreign Application Priority Data
Aug. 12, 2014 (KR) 10-2014-0104539

(51) Int. Cl. G11C 13/00

(52) U.S. Cl. CPC G11C 13/0069; G11C 13/0038; G11C 13/004

(57) ABSTRACT

A memory device is provided including a cell region including at least one cell layer, each cell layer including multiple first lines and multiple second lines; and a control region including at least one control layer. The at least one control layer includes multiple circuit regions for performing a memory operation on the cell region. The multiple first lines include at least one first signal line through which a first signal from a first circuit region of the control layer is transmitted to a second circuit region of the control layer.

### CROSS-REFERENCE TO RELATED APPLICATION

This application claims the benefit of Korean Patent Application No. 10-2014-0104539, filed on Aug. 12, 2014, in the Korean Intellectual Property Office, the disclosure of which is hereby incorporated herein by reference as if set out in its entirety.

### FIELD

The inventive concept relates generally to semiconductor devices and, more particularly, to memory devices and related systems.

### BACKGROUND

According to a demand for memory devices having a high capacity and low power consumption, a research for next-generation memory devices that are non-volatile and do not require a refresh operation is being conducted. The next-generation memory devices should have a high integrity characteristic of a Dynamic Random Access Memory (DRAM), a non-volatile characteristic of a flash memory, and a high speed of a static RAM (SRAM). As the next-generation memory devices, a Phase change RAM (PRAM), a Nano Floating Gate Memory (NFGM), a Polymer RAM (PoRAM), a Magnetic RAM (MRAM), a Ferroelectric RAM (FeRAM), and a Resistive RAM (RRAM) are being highlighted.

### SUMMARY

Some embodiments of the inventive concept provide memory devices including a cell region including at least one cell layer, each cell layer including multiple first lines and multiple second lines; and a control region including at least one control layer. The at least one control layer includes multiple circuit regions for performing a memory operation on the cell region. The multiple first lines include at least one first signal line through which a first signal from a first circuit region of the control layer is transmitted to a second circuit region of the control layer.

In further embodiments, the at least one first signal line may be at least one edge line disposed at an edge from among the multiple first lines.

In still further embodiments, access to a memory cell connected to the at least one first signal line may be prohibited.

In some embodiments, a memory cell connected to the at least one first signal line may be formed by skipping an operation of forming at least one of a variable resistor device and a selection device.

In further embodiments, a memory cell connected to the at least one first signal line may be formed by skipping performing a forming operation.

In still further embodiments, at least one of a power signal and a bias signal generated in the first circuit region may be transmitted via the at least one first signal line.

In some embodiments, the first circuit region may include a power generating unit, and the second circuit region may include a write/read circuit.

In further embodiments, the multiple second lines may include at least one second signal line through which a second signal from a third circuit region of the control layer is transmitted to a fourth circuit region of the control layer.

In still further embodiments, the cell layer may include a tile group including multiple tiles, wherein the first signal is transmitted through the at least one first signal line from a position corresponding to outside of the tile group to a position corresponding to a tile in the tile group.

Some embodiments of the present inventive concept provide memory devices including a first layer including multiple memory cells, multiple first lines connected to accessible memory cells, and at least one signal line that is connected to access-inhibited memory cells and disposed parallel to the first lines; and a second layer through which, in a memory operation, at least one of a power signal and a bias signal that are not related to a selection operation performed on the memory cells is provided to the at least one signal line.

Further embodiments of the inventive concept provide memory devices including a plurality of word lines and bit lines, the plurality of word lines being relatively perpendicular to the plurality of bit lines; and a plurality of memory cells coupled to the plurality of word lines. At least one of the plurality of words lines is positioned at an edge of the memory device and a memory cell associated with the at least one word line positioned at an edge of the memory device is not used.

In still further embodiments, the at least one word line positioned at an edge of the memory device may be configured to transmit at least one of a power signal and a bias signal. The at least one power signal and/or bias signal may be transmitted via the at least one word line positioned at the edge of the memory device through an entire cell layer.

In some embodiments, the memory device may further include at least one contact. The word line positioned at the edge of the memory device may be connected to a control layer via the at least one contact.

In further embodiments, a signal generated in a circuit of the control layer may be transmitted via the word line positioned at an edge of the memory device and may be provided to other circuits of the control layer from a node of the word line positioned at the edge of the memory device.

### BRIEF DESCRIPTION OF THE DRAWINGS

Exemplary embodiments of the inventive concept will be more clearly understood from the following detailed description taken in conjunction with the accompanying drawings in which:

FIG. 1 is a block diagram of a memory system including a memory device according to some embodiments of the inventive concept.

FIG. 2 is a block diagram of the memory device of FIG. 1 according to some embodiments of the inventive concept.

FIGS. 3A through 3D are a structural and circuit diagrams of the memory device of FIG. 2 according to some embodiments of the inventive concept.

FIGS. 4A through 4C are circuit diagrams illustrating examples of a memory cell included in the memory device of FIG. 1 in accordance with some embodiments of the present inventive concept.

FIG. 5 is a block diagram illustrating layers included in the memory device of FIG. 1 according to some embodiments of the present inventive concept.

FIG. 6 is a diagram illustrating line arrangement of a cell region according to some embodiments of the inventive concept.

FIG. 7 is a cross-section of a structure of a memory device of FIG. 6 along a line M-M′ according to some embodiments of the present inventive concept.

FIG. 8 is a block diagram illustrating a path through which a power signal or a bias signal is transmitted into a cell layer according to some embodiments of the present inventive concept.

FIGS. 9A and 9B are circuit diagrams illustrating formation of memory cells connected to an edge word line (or an edge bit line) according to some embodiments of the present inventive concept.

FIGS. 10A and 10B are diagrams illustrating formation of memory cells connected to an edge word line (or an edge bit line) according to some embodiments of the present inventive concept.

FIG. 11 is a cross-section of a memory device illustrating a structure of a tile including an edge line according to some embodiments of the inventive concept.

FIGS. 12A and 12B are diagrams illustrating a signal transmission path of a control layer and a cell layer according to some embodiments of the present inventive concept.

FIG. 13 is a diagram illustrating a memory device according to some embodiments of the inventive concept.

FIG. 14 is a plan view illustrating a line arrangement of a cell region according to some embodiments of the present inventive concept.

FIG. 15 is a diagram illustrating voltage signals provided to word lines of FIG. 14 according to some embodiments of the present inventive concept.

FIG. 16 is a block diagram of a memory device according to some embodiments of the present inventive concept.

FIG. 17 is a block diagram of a memory card system having a memory system applied thereto according to some embodiments of the present inventive concept.

FIG. 18 is a diagram illustrating a memory module according to some embodiments of the present inventive concept.

FIG. 19 is a block diagram of a computer system including a memory system according to some embodiments of the present inventive concept.

### DETAILED DESCRIPTION OF THE EMBODIMENTS

Various embodiments will now be described more fully with reference to the accompanying drawings in which some embodiments are shown. This inventive concept may, however, be embodied in different forms and should not be construed as limited to embodiments set forth herein. Rather, these embodiments are provided so that this disclosure is thorough and complete and fully conveys the inventive concept to those skilled in the art.

The terminology used herein is for the purpose of describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

While terms “first” and “second” are used to describe various components, it is obvious that the components are not limited to the terms “first” and “second”. The terms “first” and “second” are used only to distinguish between each component. For example, a first component may indicate a second component or a second component may indicate a first component without conflicting with the inventive concept.

It will be understood that when an element or layer is referred to as being “on,” “connected to,” or “coupled to” another element or layer, it may be directly on, connected, or coupled to the other element or layer or intervening elements or layers may be present. In contrast, when an element is referred to as being “directly on,” “directly connected to,” or “directly coupled to” another element or layer, there are no intervening elements or layers present. In the following explanation, the same reference numerals denote the same components throughout the specification. As used herein, the term “and/or” includes any and all combinations of one or more of the associated listed items. Expressions such as “at least one of,” when preceding a list of elements, modify the entire list of elements and do not modify the individual elements of the list.

Spatially relative terms, such as “beneath,” “below,” “lower,” “above,” “upper,” and the like, may be used herein for ease of description in describing one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein may be interpreted accordingly.

The exemplary embodiments of the inventive concept will be described with reference to cross-sections and/or plan views, which are ideal exemplary views. Thicknesses of layers and areas are exaggerated for effective description of the technical contents in the drawings. Forms of some embodiments may be modified by the manufacturing technology and/or tolerance. Therefore, some embodiments of the inventive concept are not intended to be limited to illustrated specific forms, and include modifications of forms generated according to manufacturing processes. For example, an etching area illustrated at a right angle may be round or have a predetermined curvature. Therefore, areas illustrated in the drawings have overview properties, and shapes of the areas are illustrated special forms of the areas of a device, and are not intended to be limited to the scope of the inventive concept.

Unless defined otherwise, all terms including descriptive or technical terms which are used herein should be construed as having meanings that are obvious to one of ordinary skill in the art. Furthermore, terms that are defined in a general dictionary and that are used in the following description should be construed as having meanings that are equivalent to meanings used in the related description, and unless expressly defined otherwise herein, the terms should not be construed as being ideal or excessively formal.

Hereinafter, like reference numerals in the drawings denote like elements or functionally similar elements. Therefore, such like reference numerals or similar reference numerals will not be mentioned or described in the drawings but will be understood with reference to the other drawings. Further, when such reference numerals are not illustrated, they will be understood with reference to the other drawings.

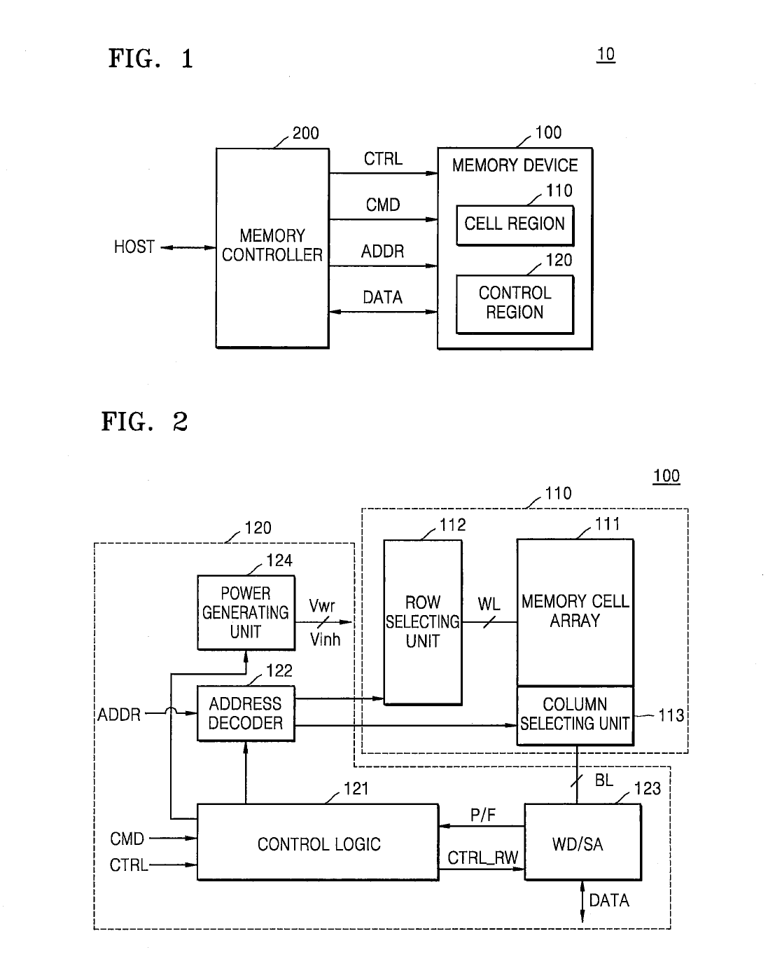

Referring first to FIG. 1, a block diagram of a memory system 10 including a memory device 100 according to some embodiments of the inventive concept will be discussed. As illustrated in FIG. 1, the memory system 10 may include a memory device 100 and a memory controller 200. The memory device 100 may include a cell region 110 and a control region 120. The cell region 110 may include a memory cell array, and the memory cell array may have a cross point array structure in which memory cells are disposed between upper electrodes formed of a plurality of first lines and lower electrodes formed of a plurality of second lines. Furthermore, as the memory cell array includes resistive memory cells, the memory device 100 may be referred to as a resistive memory device and the memory system 10 may be referred to as a resistive memory system. Hereinafter, although embodiments of the inventive concept will be described based on a resistive memory device, it will be understood that embodiments of the inventive concept may also be applied to various types of memory devices having the above-described cross point array without departing from the scope of the present inventive concept.

In response to a write/read request from a host, the memory controller 200 may control the memory device 100 such that data stored in the memory device 100 is read or data is written to the memory device 100. In particular, the memory controller 200 may provide the memory device 100 with an address ADDR, a command CMD, and a control signal CTRL and may control a programming (or write) operation, a read operation, and an erase operation on the memory device 100. Furthermore, data DATA to be written and read data DATA may be transmitted or received between the memory controller 200 and the memory device 100.

In some embodiments, the memory controller 200 may include a Random Access Memory (RAM), a processing unit, a host interface, and a memory interface. The RAM may be used as an operation memory of the processing unit. The processing unit may control operations of the memory controller 200. The host interface may include a protocol for exchanging data between the host and the memory controller 200. For example, the memory controller 200 may communicate with the host by using at least one of various interface protocols including USB, MMC, PCI-E, Advanced Technology Attachment (ATA), Serial-ATA, Parallel-ATA, SCSI, ESDI, and Integrated Drive Electronics (IDE).

The memory device 100 may have a structure in which multiple layers are stacked. For example, the cell region 110 may include at least one layer, and the control region 120 may include at least one layer. Each layer included in the cell region 110 may include a memory cell array. As described above, the memory cell array may include memory cells disposed in areas where a plurality of first lines and a plurality of second lines cross each other. According to an embodiment, the plurality of first lines may be a plurality of bit lines, and the plurality of second lines may be a plurality of word lines. In some embodiments, the plurality of first lines may be a plurality of word lines, and the plurality of second lines may be a plurality of bit lines. Furthermore, a row selecting unit and a column selecting unit including switches for selecting a memory that is to be accessed may be further included in each layer included in the cell region 110.

As illustrated in FIG. 1, each of the memory cells may be a single level cell (SLC) that stores one bit data, or may be a multilevel cell (MLC) that may store at least two-bit data. In some embodiments, the cell region 110 may include both the SLC and the MLC. When one bit data is written to one memory cell, the memory cells may have two resistance level distributions according to the written data. When two-bit data is written to one memory cell, the memory cells may have four resistance level distributions according to the written data. In some embodiments, if a memory cell is a triple level cell (TLC) that stores three-bit data, the memory cells may have eight resistance level distributions according to the written data. However, embodiments of the inventive concept are not limited to the example discussed herein. For example, each of the memory cells may store at least four-bit data or more without departing from the scope of the present inventive concept.

The cell region 110 may include resistance-type memory cells or resistive memory cells that include a variable resistor device having a variable resistor. For example, when resistance of the variable resistor device that is formed of a phase change material, for example, Ge—Sb—Te, is changed according to a temperature, a resistive memory device may be a Phase change RAM (PRAM). By way of further example, when the variable resistor device is formed of an upper electrode, a lower electrode, and a transition metal oxide (complex metal oxide) therebetween, the resistive memory device may be a Resistive RAM (RRAM). When the variable resistor device is formed of an upper electrode of a magnetic material, a lower electrode of a magnetic material, and a dielectric therebetween, the resistive memory device may be a Magnetic RAM (MRAM).

The control region 120 may include various control circuits used to perform access operations such as a write operation and a read operation on memory cells. For example, the control region 120 may include control logic for controlling overall operations of the memory device 100, an address decoder that decodes an address from the outside to select a memory cell requested to be accessed, a write/read circuit that performs a read operation and a write operation on a memory cell, and the like.

Multiple layers included in the memory device 100 may be vertically stacked. For example, a layer corresponding to the control region 120, for example, a control layer, and multiple layers corresponding to the cell region 110, for example, cell layers, may be vertically stacked. In some embodiments, multiple cell layers may be stacked on the control layer. A signal may be transmitted or received between the cell layers and the control layer via multiple signal lines that are disposed in parallel to a direction in which the layers are stacked.

In a write operation on the memory device 100, variable resistance of a memory cell may increase or be reduced according to written data. For example, each of the memory cells of the cell region 110 may have a resistance value according to currently stored data, and the resistance value of the cell region 110 may increase or be reduced according to data that is to be written to each of the memory cells. A write operation, as discussed above, may be classified as a reset write operation and a set write operation. A set state in a resistive memory cell may have a relatively low resistance value, whereas a reset state may have a relatively high resistance value. In a reset write operation, a write operation is performed in a direction in which variable resistance increases, and in a set write operation, a write operation is performed in a direction in which variable resistance is reduced.

In regard to a write operation and a read operation on the cell region 110, memory cells that are to be accessed and memory cells that are not to be accessed need to be electrically separated, and to this end, appropriate line biasing on first and second lines is required. For example, a selection voltage may be provided to first and second lines connected to memory cells to be accessed (e.g., selected lines), whereas an inhibit voltage may be provided to other first and second lines (e.g., non-selected lines) so that other memory cells are not selected.

Although the cell region 110 described above includes only a memory cell array and switches, the embodiments of the inventive concept are not limited thereto. The control region 120 may include other various peripheral circuits for a memory operation in addition to the control logic, the address decoder, and the write/read circuit, and at least some circuits included in the control region 120 may also be included in the cell region 110.

In order to select memory cells, first lines (hereinafter referred to as word lines) and second lines (hereinafter referred to as bit lines) disposed in each cell layer of the cell region 110 may be used as a signal path via which voltages for a write operation or a read operation are provided. A selection voltage (e.g., a set voltage or a reset voltage) may be transmitted to word lines and bit lines connected to selected memory cells, and a predetermined non-selected voltage (e.g., an inhibit voltage) may be transmitted to word lines and bit lines connected to non-selected memory cells. According some embodiments of the inventive concept, at least one of the word lines and the bit lines is used as a signal line for transmitting or receiving a signal to and from the control region 120. For example, at least one of the multiple word lines is a signal of a different type from other word lines, and may be used, for example, as a signal line for transmitting signals such as a power signal or a bias signal.

To perform a memory operation, a selection operation on multiple word lines and multiple bit lines is to be controlled as discussed above, and to this end, multiple decoding circuits are to be disposed in the control region 120. Furthermore, a write/read circuit for a read operation and a write operation on selected memory cells and other circuits may be disposed in the control region 120. For example, if a cell array includes multiple memory cell units (e.g., multiple tile units); a write/read circuit may be disposed in a control array at a position corresponding to the multiple tile units. Here, it may be difficult to secure a line region where a power signal or a bias signal or the like is provided to a circuit region, for example, a write/read circuit disposed at a corresponding to the inside of the tiles from the circuit region corresponding to the outside of the tiles in the control array. In embodiments of FIG. 1, a word line and/or a bit line disposed in a direction across a cell layer may be used as signal line for transmitting signals such as a power signal or a bias signal, and signals transmitted via the signal line may be provided to various circuit regions in the control region 120, thereby forming an efficient signal transmission path.

The memory controller 200 and the memory device 100 may be integrated to a semiconductor device. For example, the memory controller 200 and the memory device 100 may be integrated to a semiconductor device and thus may configure a memory card. For example, the memory controller 200 and the memory device 100 may be integrated to a semiconductor device and thus may configure a PC card (a PCMCIA card), a compact flash card (CF card), a smart media card (SM/SMC), a memory stick, a multimedia card (MMC, RS-MMC, or MMCmicro, an SD card (SD, miniSD, or microSD), or a universal flash storage (UFS). In some embodiments, the memory controller 200 and the memory device 100 may be integrated to a semiconductor device and thus may configure a Solid State Disk/Drive (SSD).

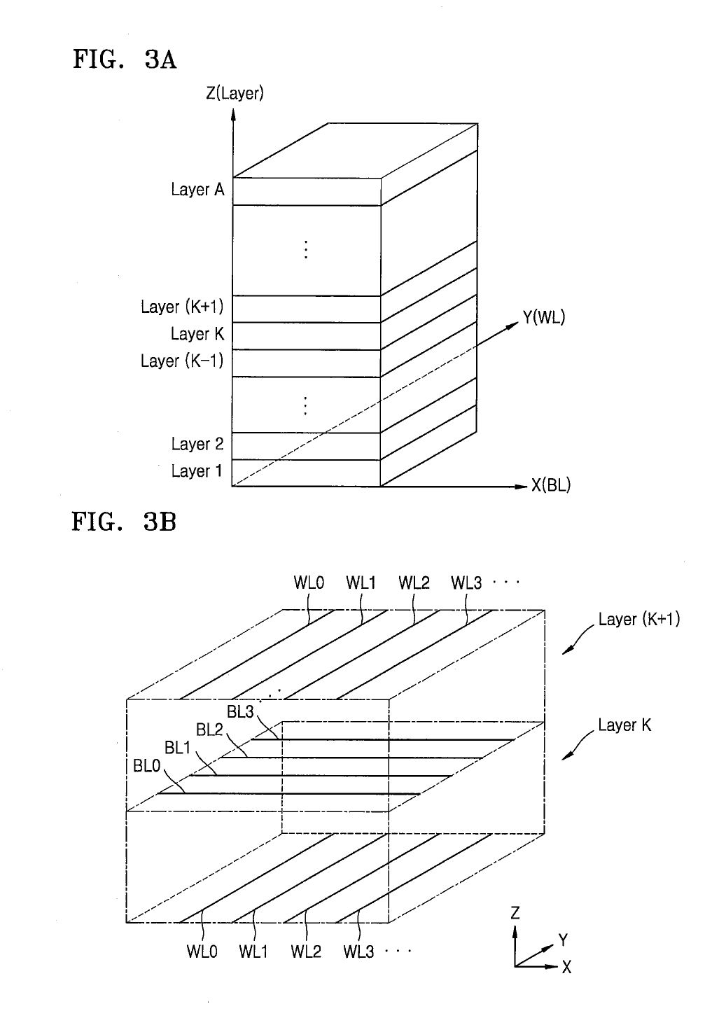

FIG. 2 is a block diagram of the memory device 100 of FIG. 1 in accordance with some embodiments of the inventive concept. Operations of the memory device 100 included in the memory system 10 as discussed above will be discussed. As illustrated in FIG. 2, the memory device 100 may include the cell region 110 and the control region 120. The cell region 110 may include a memory cell array 111, a row selecting unit 112, and a column selecting unit 113. Furthermore, the control region 120 may include control logic 121, an address decoder 122, a write/read circuit 123, and a power generating unit 124. The write/read circuit 123 may include a write driver WD and a sense amp SA. Furthermore, the memory device 100 may include multiple layers that are vertically stacked, and elements included in the cell region 110 may be disposed in some layers, and elements included in the control logic 120 may be disposed in other layers.

A structure and an operation of the memory device 100 illustrated in FIG. 2 will now be discussed. Memory cells included in the cell region 110 may be connected to a plurality of word lines WL and a plurality of bit lines BL. As various voltage signals or current signals are provided through a plurality of word lines WL and a plurality of bit lines BL (hereinafter, a signal provided to word lines WL and bit lines BL is defined as a voltage signal), data may be written to or read from some selected memory cells, and non-selected memory cells may be prevented from being written or read.

Meanwhile, an address ADDR for indicating a memory cell to be accessed may be received with a command CMD, and the address ADDR may include a row address for selecting word lines WL of the memory cell array 111 and a column address for selecting bit lines BL of the memory cell array 111. The address decoder 122 may decode the address ADDR and output the decoded address, and the row selecting unit 112 and the column selecting unit 113 each perform a selecting operation on the word lines WL and the bit lines BL in response to the decoded address.

The write/read circuit 123 may be connected to the bit lines BL to write data to a memory cell or read data from a memory cell. For example, the write/read circuit 123 may receive a write/read voltage Vwr from the power generating unit 124, and the write driver WD may provide the memory cell array 111 with a received write voltage via the column selecting unit 113. In a set write operation, the write driver WD may reduce a resistance value of variable resistance of a memory cell by providing the memory cell array 111 with a set voltage. In addition, in a reset write operation, the write driver WD may increase a resistance value of variable resistance of a memory cell by providing the memory cell array 111 with a reset voltage. On the other hand, an inhibit voltage Vinh may be applied to non-selected memory cells, thereby reducing the likelihood that the non-selected memory cells will be accessed.

Meanwhile, in a data read operation, the write/read circuit 123 may provide a read voltage to a memory cell. Furthermore, to determine data, the sense amp SA may include a comparing unit that is connected to a node of a bit line, for example, a sensing node. An end of the comparing unit may be connected to a sensing node, and the other end may be connected to a reference voltage source so that data may be determined. Furthermore, the write/read circuit 123 may provide the control logic 121 with a pass/fail signal P/F according to a result of determining read data. The control logic 121 may control a write operation and a read operation of the memory cell array 111 by referring to the pass/fail signal P/F.

The control logic 121 may output various control signals CTRL_RW for writing data to the memory cell array 111 or reading data from the memory cell array 111 based on a command CMD, an address ADDR, and a control logic CTRL received from the memory controller 200. Accordingly, the control logic 121 may control various operations in the memory device 100 overall.

According some embodiments of the inventive concept, the memory device 100 includes A layers (A is an integer equal to or greater than 2), and a first layer disposed in a lowermost portion corresponds to a control layer and thus includes the control region 120, and multiple layers disposed on the first layer, for example, second through Ath layers, correspond to cell layers and thus may include the cell region 110. Furthermore, signals may be transmitted or received between various circuit regions included in the control region 120. In addition, signals for controlling a plurality of word lines WL and a plurality of bit lines BL may be transmitted or received between the cell region 110 and the control region 120 via multiple signal lines disposed to correspond to a stacking direction of the layers.

Furthermore, some word lines and/or some bit lines may be used as a signal line not for selecting a memory cell but for transmitting signals of other types. According to some embodiments, a word line and/or a bit line used as the above-described signal line may be disposed at an edge of the memory cell array, and thus may be referred to as an edge word line or an edge bit line. However, this is exemplary, and a word line and/or a bit line used as the above-described signal line may also be disposed inside the memory cell array without departing from the scope of the present inventive concept. Hereinafter, the above-described signal line will be referred to as an edge word line or an edge bit line for convenience of description.

A write operation and a read operation are not performed on a memory cell connected to the edge word line and/or the edge bit line, and thus, at least a portion of a memory cell process or a forming process on the formed memory cell may be skipped. Consequently, the edge word line and/or the edge bit line may be physically or electrically separated from other lines adjacent thereto. Furthermore, the edge word line and/or the edge bit line may be electrically connected to multiple circuit regions of the control region 120 via contact connection. For example, a signal provided from a circuit region of the control region 120 may be transmitted via an edge word line and/or an edge bit line of the cell region 110, and the signal transmitted via the edge word line and/or the edge bit line may be provided to other circuit regions of the control region 120. If the power generating unit 124 generates a power signal or a bias signal, the power signal or the bias signal may be transmitted via the edge word line and/or the edge bit line, and the power signal or the bias signal may be provided to other circuit regions of, for example, the write/read circuit 123 in the control region 120.

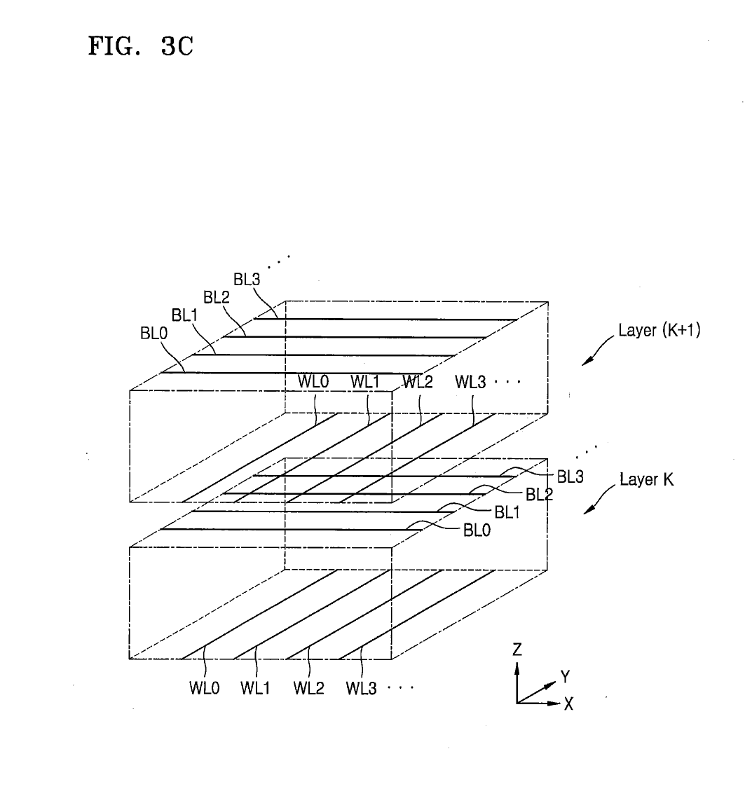

Referring now to FIGS. 3A through 3D, structural and circuit diagrams of the memory device 100 of FIG. 2 in accordance with some embodiments of the inventive concept will be discussed. FIG. 3A is a structural diagram illustrating the entire structure of the memory device 100, and FIGS. 3B and 3C are structural diagrams illustrating arrangement of word lines and bit lines of layers corresponding to the cell region 110, and FIG. 3D is a circuit diagram of the memory cell array 111. Referring first to FIG. 3A, the memory device 100 has a three-dimensional structure, and includes two-dimensional memory layers on an X-Y plane that are stacked in a Z-axis direction. According to some embodiments, a total of A layers, from a lowermost layer (Layer 1) through an uppermost layer (Layer A) are illustrated. An X-axis may be a wiring direction of bit lines BL included in the cell region, a Y-axis may be a wiring direction of word lines WL included in the cell region, and a Z-axis may be a stacking direction of layers Layer 1 through Layer A.

As illustrated in FIG. 3B, a plurality of word lines WL0, WL1, WL2, and WL3 and a plurality of bit lines BL0, BL1, BL2, and BL3 may be respectively disposed on a lower surface and an upper surface of a layer, for example, a K-th layer, to orthogonally cross each other when they are projected onto a X-Y plane, and may be alternately disposed along a stacking direction of the layers (Z-axis direction). According to some embodiments, a plurality of word lines WL0, WL1, WL2, and WL3 and a plurality of bit lines BL0, BL1, BL2, and BL3 disposed in the K-th layer (Layer K) may be shared by other layers, for example, a (K−1)th layer and a (K+1)th layer.

As illustrated in FIG. 3C, each layer may include word lines WL0, WL1, WL2, and WL3 and bit lines BL0, BL1, BL2, and BL3 without sharing a line with other layers. For example, a plurality of word lines WL0, WL1, WL2, and WL3 and a plurality of bit lines BL0, BL1, BL2, and BL3 are respectively disposed on a K-th layer (Layer K), and in the same direction, a plurality of word lines WL0, WL1, WL2, and WL3 and a plurality of bit line BL0, BL1, BL2, and BL3 may also be disposed on a K+1th layer (Layer K+1).

As illustrated in FIG. 3D the memory cell array 111 included in each layer may be a horizontal two-dimensional memory, and may include a plurality of word lines WL1 through WLn, a plurality of bit lines BL1 through BLm, and a plurality of memory cells MC. The number of the word lines WL, the bit lines BL, and the memory cells MC may be modified according to some embodiments. Furthermore, a set of memory cells that may be accessed simultaneously by the same word line may be defined as a page.

According to some of embodiments of the present inventive concept, each of the plurality of memory cells MC may include a variable resistor device R and a selection device D. The variable resistor device R may be referred to as a variable resistance material, and the selection device D may be referred to as a switching device.

According to some embodiments, the variable resistor device R is connected between one of a plurality of bit lines BL1 through BLm and the selection device D, and the selection device D may be connected between the variable resistor device R and one of a plurality of word lines WL1 through WLn. However, the embodiments of the inventive concept are not limited thereto, and the selection device D may be connected between one of a plurality of bit lines BL1 through BLm and the variable resistor device R, and the variable resistor device R may be connected between the selection device D and one of a plurality of word lines WL1 through WLn without departing from the scope of the present inventive concept.

The selection device D may be connected between one of the plurality of word lines WL1 through WLn and the variable resistor device R, and may control a current supply to the variable resistor device R according to a voltage applied to the connected word line and bit line. While a diode is illustrated as the selection device D in FIG. 3, this is merely an exemplary embodiments of the inventive concept. In some embodiments the selection device D may be modified to other switchable devices without departing from the scope of the present inventive concept.

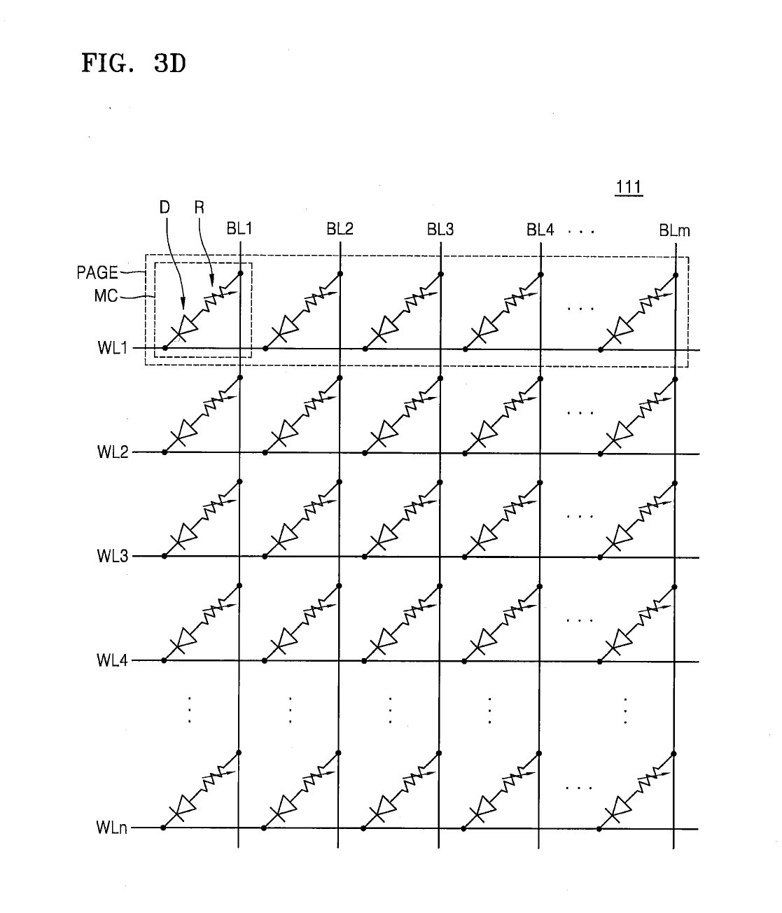

Referring now to FIGS. 4A through 4C, circuit diagrams illustrating examples of a memory cell included in the memory device 100 of FIG. 1 will be discussed. As illustrated in FIG. 4A, a memory cell MCa may include a variable resistor device Ra that may be connected between a bit line BL and a word line WL. The memory cell MCa may store data due to voltages that are respectively applied to the bit line BL and the word line WL.

As illustrated in FIG. 4B, a memory cell MCb may include a variable resistor device Rb and a bidirectional diode Db. The variable resistor device Rb may include a resistive material so as to store data. The bidirectional diode Db may be connected between the variable resistor device Rb and a word line WL, and the variable resistor device Rb may be connected between a bit line BL and the bidirectional diode Db. Positions of the bidirectional diode Db and the variable resistor device Rb may be changed with respect to each other. By using the bidirectional diode Db, a leakage current that may flow to a non-selected resistor cell may be reduced.

As illustrated in FIG. 4C, a memory cell MCc may include a variable resistor device Rc and a transistor TR. The transistor TR may be a selection device that supplies or blocks a current to the variable resistor device Rc according to a voltage of the word line WL, In particular, a switching device. The transistor TR may be connected between the variable resistor device Rc and the word line WL, and the variable resistor device R may be connected between a bit line BL and the transistor TR. Positions of the transistor TR and the variable resistor device Rc may be changed with respect to each other. The memory cell MCc may be selected or not selected according to ON or OFF of the transistor TR that is driven by the word line WL.

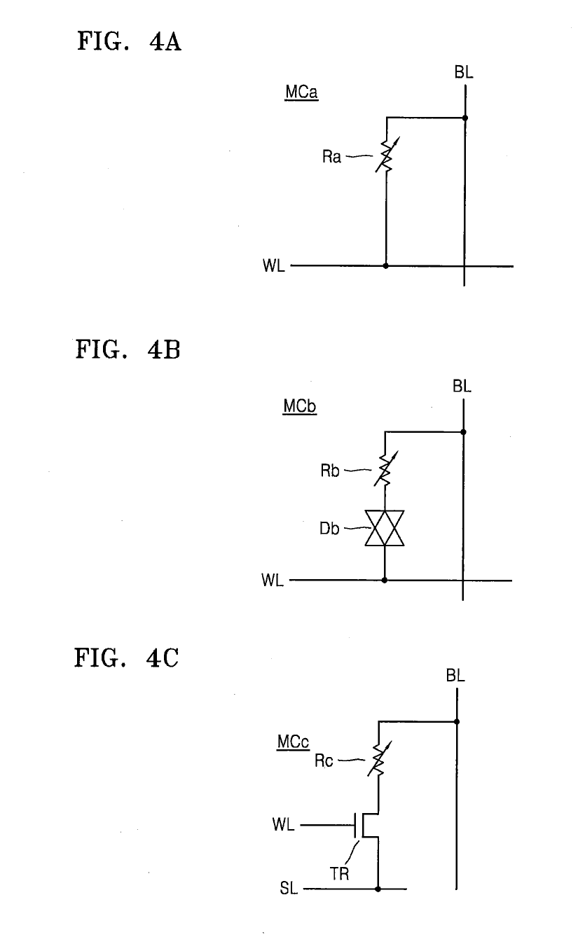

Referring now to FIG. 5, a diagram illustrating layers included in the memory device 100 of FIG. 1 according to some embodiments of the present inventive concept will be discussed. As illustrated in FIG. 5, the memory device 100 may include multiple layers, for example, A layers (Layer 1 through Layer A). As further illustrated, a first layer in a lower portion corresponds to a control layer (Layer 1) and thus includes the control region 120, and second through Ath layers stacked on the first layer correspond to cell layers (Layer 2 through Layer A) and thus each include the cell region 110.

The control layer (Layer 1) may include a control logic 121, an address decoder 122, a write/read circuit 123, a power generating unit 124, and a peripheral circuit 125. The address decoder 122 may decode an address from the outside and output the decoded address. The decoded address may include a row address for selecting word lines WL of a cell region and a column address for selecting bit lines BL of the cell region.

According to some embodiments of the inventive concept, various signals may be transmitted and received between the control layer (Layer 1) and the cell layers (Layer 2 through Layer A) via multiple signal lines formed in a stacking direction of the layers. For example, a row address and a column address from the address decoder 122 may be respectively transmitted via a global word line GWL and a global bit line GBL. The row address and the column address may be respectively provided to a row selecting unit and a column selecting unit of the cell layers (Layer 2 through Layer A).

Word lines (or local word lines WL) and bit lines (or local bit lines BL) may be disposed in each of the cell layers (Layer 2 through Layer A). According to a selection operation of the row selecting unit and the column selecting unit, some word lines and some bit lines may be selected, and other word lines and other bit lines may not be selected. Furthermore, as described above, at least one of multiple word lines WL of each of the cell layers (Layer 2 through Layer A) may correspond to an edge word line EWL, and Furthermore, at least one of multiple bit lines BL may correspond to an edge bit line EBL. In other words, multiple word lines WL may be defined as including normal word lines and at least one edge word line EWL, and Furthermore, the multiple bit lines BL may be defined as including normal bit lines and at least one edge bit line EBL. For example, when multiple word lines WL are classified as normal word lines and an edge word line EWL, the word lines WL illustrated in FIG. 5 may correspond to normal word lines.

Various signals from the first layer is provided to the edge word line EWL and/or the edge bit line EBL, and various signals transmitted via the edge word line EWL and/or the edge bit line EBL may be provided to the first layer (Layer 1). For example, a line via which a signal generated in the first layer is provided to the edge word line EWL and/or the edge bit line EBL may be referred to as a first group line (Line_G1), and a line via which a signal transmitted through the edge word line EWL and/or the edge bit line EBL is provided to the first layer (Layer 1) may be referred to as a second group line (Line_G2).

To perform a memory operation, signals have to be transmitted between various circuit regions in the control layer (Layer 1), and Furthermore, various signals have to be transmitted between the control layer (Layer 1) and the cell layers (Layer 2 through Layer A). For example, multiple decoding circuits included in the address decoder 122 are distributed in the control layer (Layer 1) in order to perform a selection operation on the word lines WL and the bit lines BL of the cell layers (Layer 2 through Layer A) as illustrated in FIG. 5, and thus, it may be difficult to secure a transmission region where various signals are transmitted between circuit regions in the control layer (Layer 1). According to some embodiments of the inventive concept, at least some signals may be provided to the edge word line EWL and/or the edge bit line EBL via the first group line Line_G1, and a signal transmitted via the edge word line EWL and/or the edge bit line EBL may be provided to a circuit region of the control layer (Layer 1) via a second group line Line_G2. For example, a power signal and a bias signal or the like generated in the power generating unit 124 may be provided to the read/read circuit 123 via the edge word line EWL and/or the edge bit line EBL.

The edge word line EWL and the edge bit line EBL are disposed across a cell layer (or a control layer) in an x-axis direction or a y-axis direction, and accordingly, in circuit regions where it is difficult to secure a line region for transmitting or receiving signals between each other, signals may be easily transmitted and received by using the edge word line EWL and/or the edge bit line EBL. For example, when transmitting a power signal or a bias signal or the like to the write/read circuit 123 disposed to correspond to tiles of each of the cell layers (Layer 2 through Layer A), the edge word line EWL and/or the edge bit line EBL formed in the cell layers (Layer 2 through Layer A) may be used in signal transmission without increasing a distance between the tiles to secure a line region, and thus, the total size of the memory device 100 may be reduced.

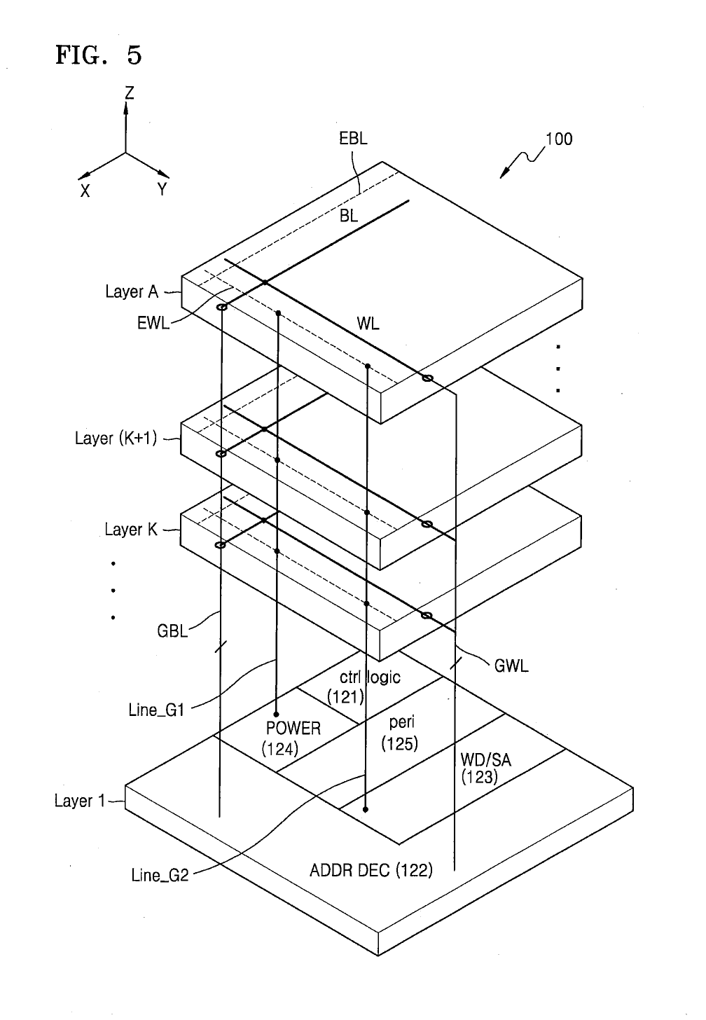

Referring now to FIG. 6, a diagram illustrating a line arrangement of a cell region according to some embodiments of the inventive concept will be discussed. As illustrated in FIG. 6, word lines WL and bit line BL disposed in one cell layer are illustrated, and a write/read circuit illustrated in FIG. 6 may be disposed in a control layer located below a cell layer. Furthermore, word lines WL that are connected to a memory cell that normally stores data and edge word lines Edge WL1 and Edge WL2, via which various signals such as a power signal or a bias signal are transmitted, are divided in FIG. 6, and compared to the edge word lines Edge WL1 and Edge WL2, the word lines WL may be referred to as normal word lines. Similarly, the bit lines BL may be referred to as normal bit lines.

The memory device 100 may include multiple cell layers in which a cell array is disposed, and each of the cell layers may include multiple tiles. The tiles may be defined in various manners. For example, a tile may be defined as a unit that includes a cell array connected to multiple word lines WL that share the same row selecting unit and to multiple bit lines BL that share the same column selecting unit.

A cell layer may include multiple word lines WL and multiple bit lines BL, and for example, the multiple word lines WL and multiple bit lines BL may be disposed in each tile. Furthermore, the multiple word lines WL may be disposed to be parallel to a first direction, for example, an x-axis direction, of the cell layers, whereas the multiple bit lines BL may be disposed to be parallel to a second direction of the cell layers, for example, a y-axis direction, of the cell layers. Furthermore, memory cells may be disposed in areas where the multiple word lines WL and the multiple bit lines BL cross each other.

Furthermore, according to some embodiments discussed above, at least one edge word line may be disposed parallel to the multiple word lines WL. For example, as illustrated in FIG. 6, at least one first edge word line Edge WL1 may be disposed at an edge on a first side of the multiple word lines WL, and at least one second edge word line Edge WL2 may be disposed at an edge on a second side of the multiple word lines WL. The first and second edge word lines Edge WL and Edge WL2 may be commonly disposed with respect to multiple tiles, and accordingly, a signal transmitted through the first and second edge word lines Edge WL1 and Edge WL2 may be transmitted across the tiles. Thus, when multiple tiles are defined as a tile group, a signal may be transmitted via the first and second edge word lines Edge WL1 and Edge WL2, from a position corresponding to the outside of the tile group including multiple tiles to a position corresponding to the tiles in the tile group.

In embodiments illustrated in FIG. 6, memory cells of different tiles may be simultaneously accessed, and thus, word lines WL and bit lines BL may be dividedly disposed according to the tiles. On the other hand, the first and second edge word lines Edge WL1 and Edge WL2 may commonly provide the tiles with a power signal or a bias signal or the like. In some embodiments, multiple lines are disposed along an x-axis and a y-axis, and the multiple word lines WL may be formed by cutting a portion of the lines according to respective tiles, and whereas the first and second edge word lines Edge WL1 and Edge WL2 may be formed as a cutting process is skipped with respect to other lines, for example, lines on the edge.

According to some embodiments, various signals such as a power signal and a bias signal may be transmitted through the first and second edge word lines Edge WL1 and Edge WL2. For example, a power signal or a bias signal from a circuit region of a control array disposed at a position corresponding to the outside of a cell array or the like may be provided to the first and second edge word lines Edge WL1 and Edge WL2, and the power signal or the bias signal or the like may be provided to the tiles inside the cell array via the first and second edge word lines Edge WL1 and Edge WL2. Furthermore, a dotted line illustrated in FIG. 6 denotes a contact formed on the first and second edge word lines Edge WL1 and Edge WL2. The first and second edge word lines Edge WL1 and Edge WL2 and the control layer may be electrically connected to each other via the contact. For example, as illustrated in FIG. 6, a power signal and a bias signal transmitted through the first and second edge word lines Edge WL1 and Edge WL2 may be provided to a write/read circuit of a control array disposed at a position corresponding to tiles in the cell array through the contact.

While some of the word lines WL are used as edge word lines in FIG. 6, the embodiments of the inventive concept are not limited thereto, and at least one edge bit line may be further included in the cell array. Furthermore, while some of multiple word lines WL are used as edge word lines, the multiple word lines and the edge word lines may be defined as additional lines. In particular, it may be described that multiple word lines may be disposed, and the edge word lines may be further disposed parallel to the multiple word lines.

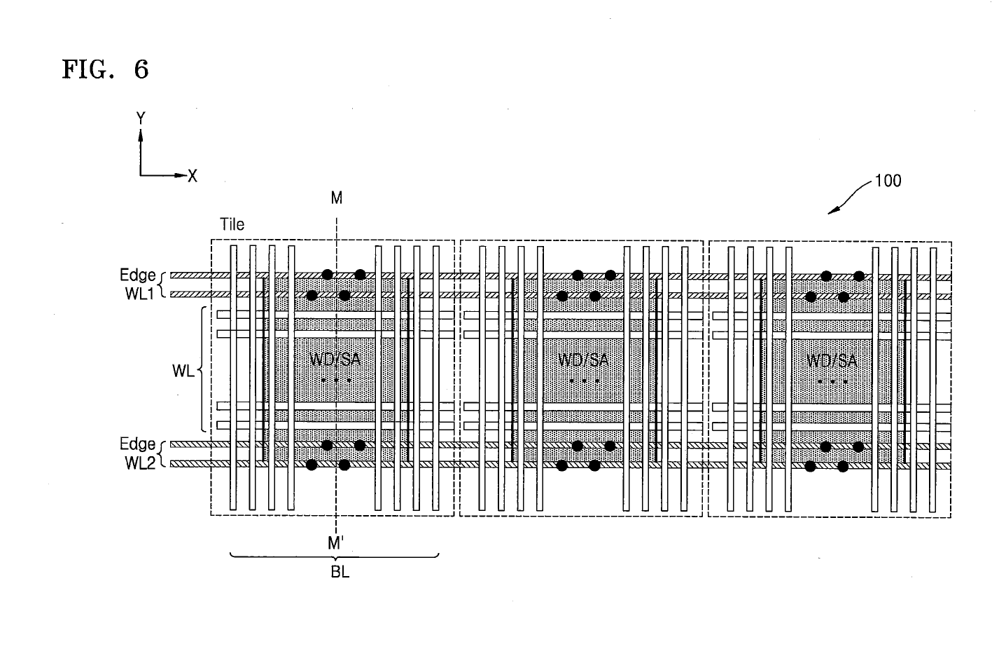

Referring now to FIG. 7, a cross-section of a structure of the memory device of FIG. 6 cut along a line M-M′ according to some embodiments of the present inventive concept will be discussed. As illustrated in FIG. 7, multiple layers are stacked, and every two adjacent layers share a word line or a bit line. In particular, a lower layer is a control layer (Layer 1) that includes a control region, and a sense amp, a write driver, and a decoder or the like may be disposed in the control layer (Layer 1). Furthermore, cell layers (Layer 2, Layer 3, Layer 4, . . . ) including multiple word lines, multiple bit lines, and memory cells may be stacked on the control layer (Layer 1).

In each cell layer, at least one edge line (for example, an edge word line or an edge bit line) may be disposed. If multiple cell layers sequentially share a word line and a bit line, an edge word line may be disposed in a cell layer, and an edge bit line may be disposed in another cell layer adjacent to the above cell layer. For example, when a second layer (Layer 2) and a third layer (Layer 3) share a bit line, an edge word line may be disposed in the second layer (Layer 2), and an edge bit line may be disposed in the third layer (Layer 3). As illustrated in FIG. 7, if edge word lines are disposed on two sides of the multiple word lines WL, an edge word line disposed on a first side may be referred to as a first edge word line Edge WL1, and an edge word line disposed on a second side may be referred to as a second edge word line Edge WL2. Various signals (PB) such as a power signal or a bias signal may be transmitted through the first and second edge word lines Edge WL1 and Edge WL2.

Meanwhile, according to some embodiments of the inventive concept, at least one of processes for forming a memory cell may be skipped with respect to memory cells connected to an edge word line or an edge bit line or a forming process on a memory cell may be skipped. For example, as illustrated in FIG. 7, at least one some of processes for forming a memory cell or a forming process is skipped, and thus, each of the first and second edge word lines Edge WL1 and Edge WL2 may be physically or electrically separated from adjacent lines (e.g., bit lines BL0, BL1, . . . ). In particular, as access to memory cells connected to the first and second edge word lines Edge WL1 and Edge WL2 is not performed, the first and second edge word lines Edge WL1 and Edge WL2 may be used as lines for transmitting various other signals to the cell layers.

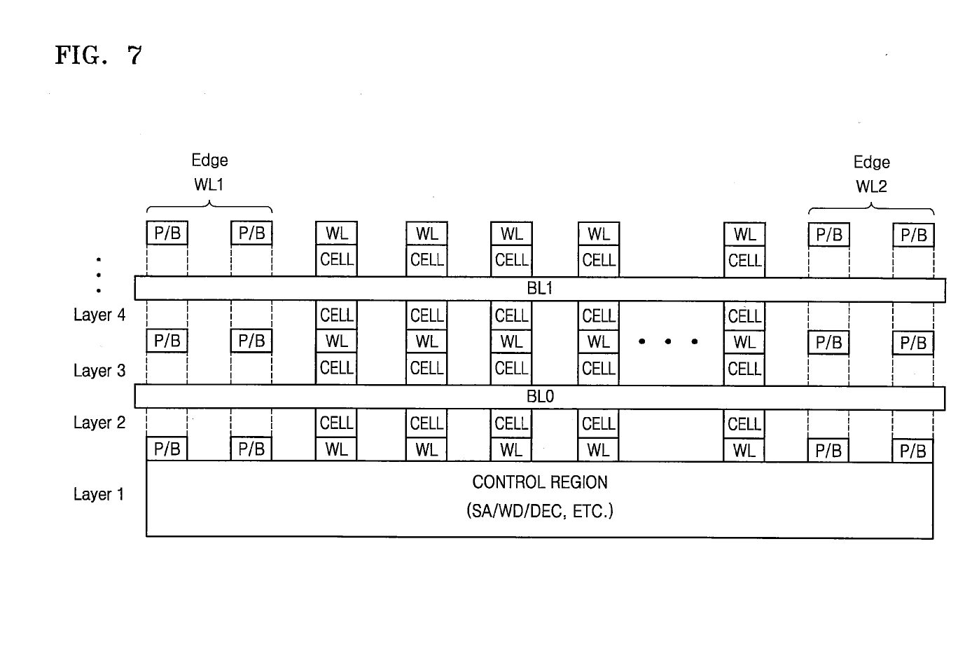

Referring now to FIG. 8, a block diagram illustrating a path through which a power signal or a bias signal is transmitted to a cell layer according to some embodiments of the inventive concept will be discussed. A portion of a control region illustrated in FIG. 8 may be disposed in a control layer disposed under the cell layer. As illustrated in FIG. 8, signal lines for selecting a word line and a bit line may be disposed around tiles, and signal lines for row decoding may be disposed at a side of a group including multiple tiles, and space formed by distances between the tiles may be used as a region where signal lines for column decoding are disposed. According to some embodiments of the inventive concept, at least one signal needed for a memory operation is used as an edge word line (or an edge bit line), and contacts that electrically connect the edge word line (or the edge bit line) and the control layer may be formed. Various signals from the control layer may be provided to an upper layer (e.g., the cell layer) along a vertical line formed parallel to a direction in which multiple layers are stacked (e.g., a z-axis direction), and the edge word line (or the edge bit line) and the vertical line may be electrically connected to each other via the contacts. Accordingly, as various signals such as a power signal or a bias signal are transmitted via the tiles in the cell layer, there is no need to provide additional space outside the tiles in order to transmit the power signal or the bias signal or the like, and thus, there is no increase in size of the memory device due to provision of the space.

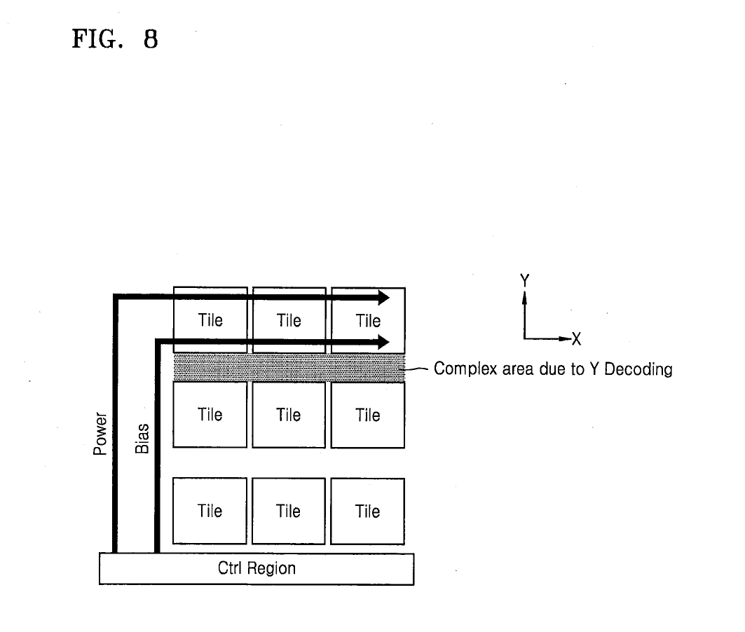

Referring now to FIGS. 9A and 9B, circuit diagrams illustrating formation of memory cells connected to an edge word line (or an edge bit line) according to some embodiments will be discussed. As illustrated in FIGS. 9A and 9B, an example of skipping at least one of processes for forming a memory cell is illustrated. In addition, a Kth layer (Layer K) is illustrated as a cell layer in FIGS. 9A and 9B.

As illustrated in FIGS. 9A and 9B, a process for forming multiple memory cells may be performed on the Kth layer (Layer K), and for example, a process of forming a variable resistor device and a selection device included in a memory cell may be performed. Some of memory cells included in the Kth layer (Layer K) are memory cells that are connected between a word line and a bit line, for example, a normal word line and a normal bit line, and to which data is stored normally, whereas some other memory cells included in the Kth layer (Layer K) may correspond to a memory cell that is connected to an edge word line or an edge bit line and to which data access is prohibited.

FIG. 9A illustrates an example of skipping a process of forming a variable resistor device included in a memory cell connected to an edge word line (or an edge bit line). Furthermore, FIG. 9B illustrates an example of skipping a process of forming a variable resistor device and a selection device included in a memory cell connected to an edge word line (or an edge bit line). The edge word line (or the edge bit line) may be connected to a first end of the memory cell on which at least one process is skipped as described above, and a normal bit line (or a normal word line) that is used in selecting a memory cell may be connected to a second end of the memory cell. Accordingly, the edge word line (or the edge bit line) may be physically separated from other adjacent lines thereto, and the edge word line (or the edge bit line) may be used as a line for transmitting other signals such as a power signal or a bias signal.

Although FIGS. 9A and 9B illustrate an example of skipping at least one of multiple processes for forming a memory cell, it will be understood that embodiments of the inventive concept are not limited thereto. For example, multiple processes may also be performed on the Kth layer (Layer K) to form other elements besides a memory cell, and at least one of the processes may be skipped. A process of forming at least one contact for electrically connecting a memory cell and a word line (or a bit line) may be performed on the Kth layer (Layer K), and by skipping forming of a contact that electrically connects the edge word line and the memory cell, the edge word line may be physically separated from other adjacent layers thereto.

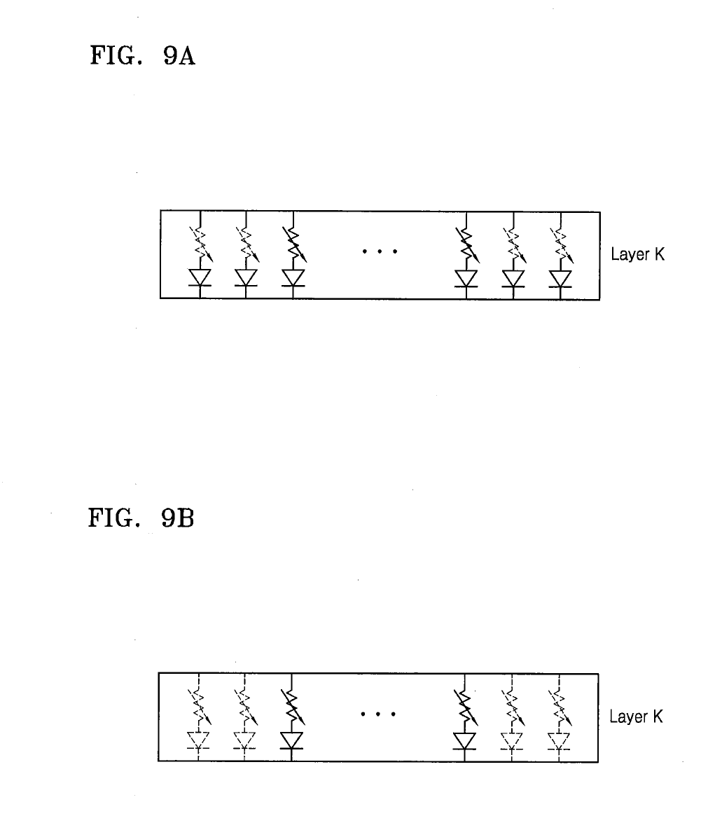

Referring now to FIGS. 10A and 10B, diagrams illustrating formation of memory cells connected to an edge word line (or an edge bit line) according to some embodiments of the inventive concept will be discussed. FIG. 10A is a graph showing current-voltage characteristics of a bidirectional type resistive memory cell, and FIG. 10B is a cross-section of electrical separation of an edge word line (or an edge bit line) from other adjacent lines.

As illustrated in FIG. 1 OA, in a set write operation, as a set current Iset corresponding to a set voltage Vset is applied to a memory cell, a resistance state of variable resistance of the memory cell may be changed from a high resistance state (HRS) to a low resistance state (LRS). Furthermore, in a reset write operation, a resistance of variable resistance of the memory cell may be changed from a LRS to a HRS by limiting an amount of a reset voltage Vreset. Furthermore, in a read operation, as a predetermined read voltage Vread is applied to a memory cell, a read current corresponding to a state of variable resistance of the memory cell is generated, and data may be determined by comparing the read current with a reference current Iref.

Meanwhile, when a memory cell is formed by using a memory cell process, a forming process may be performed on the memory cell so that the memory cell may normally store data. The forming process refers to a process of generating a filament by applying a high voltage and a high current to a memory cell in an initial state where the filament is not formed yet, which is a path, through which a current flows in the memory cell. In the forming process, a forming voltage Vforming which is higher than the set voltage Vset and a forming current Iforming according to the forming voltage Vforming are applied to the memory cell to generate a filament.

As illustrated in FIG. 10B, a first layer (Layer 1) corresponds to a control layer, and the control layer (Layer 1) may include, as various peripheral circuits related to a memory operation, a sense amp, a write driver, and various decoders. Furthermore, multiple layers are disposed on the control layer, and for example, second through fifth layers (Layer 2 through Layer 5) may correspond to a cell layer.

The second through fifth layer (Layer 2 through Layer 5) each include memory cells disposed in areas where a plurality of word lines and a plurality of bit line cross each other. According to some embodiments of the inventive concept, at least some word lines and/or bit lines may be used lines via which a power signal or a bias signal is transmitted. For example, at least one word line may be used as an edge word line EWL0 and EWL1. As illustrated in FIG. 10B, a normal forming process is performed on memory cells connected to normal word lines WL0 through WL3, whereas a forming process may be skipped on memory cells connected to edge word lines EWL0 and EWL1.

As a forming process may be skipped on the memory cells connected to the edge word lines EWL0 and EWL1, the memory cells on which a forming process is skipped have a very high resistance state, and accordingly, the edge word lines EWL0 and EWL1 may be electrically separated from other layers that are adjacent thereto and are orthogonally disposed. For example, an edge word line EWL0 shared by the second layer (Layer 2) and the third layer (Layer 3) are electrically separated from other bit lines BL0 and BL1 adjacent thereto. Furthermore, the edge word line ELW1 shared by the fourth layer (Layer 4) and the fifth layer (Layer 5) are electrically separated from other bit lines BL1 and BL2 adjacent thereto.

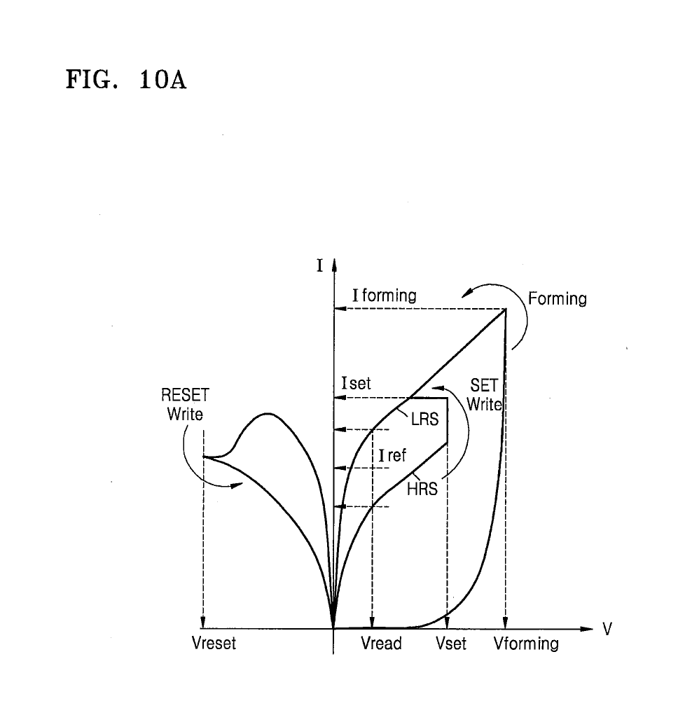

Referring now to FIG. 11, a cross-section of a memory device 100, showing a structure of a tile including an edge line according to some embodiments of the inventive concept will be discussed. According embodiments of FIG. 11, some of multiple bit lines are used as an edge bit line EBL, and a voltage level applied to word lines and bit lines represents examples of various voltages provided in a set write operation. Furthermore, although not illustrated in FIG. 11, some word lines of the memory device 100 may also be further used as an edge word line.

As illustrated in FIG. 11, the memory device 100 includes multiple layers, and for example, a first layer (Layer 1) in a lowermost portion may correspond to a control layer, and multiple layers (Layer 2 through Layer 7) stacked on the first layer may correspond to cell layers. Furthermore, each of the cell layers (Layer 2 through Layer 7) may include multiple tiles. For example, a tile may be defined as a unit that includes memory cells disposed in multiple cell layers. Furthermore, a write/read circuit 223 and decoding circuits 222_1 and 222_2 may be disposed in the control layer (Layer 1) to correspond to positions of the tiles. When the multiple cell layers (Layer 2 through Layer 7) include multiple tiles, the write/read circuit 223 and the decoding circuits 222_1 and 222_2 corresponding to the respective tiles may be disposed in the control layer (Layer 1).

Meanwhile, as a set write operation is performed, a set voltage Vset of about 4V may be applied to a bit line connected to selected memory cells, and an inhibit voltage Vinhibit of about 1V may be provided to other bit lines in order to prevent non-selected memory cells from being accessed. Furthermore, a write voltage of about 0V may be applied to a word line connected to the selected memory cells, and an inhibit voltage corresponding to about 3V may be applied to other word lines. Along with this, a power signal and a bias signal or the like is to be provided to the write/read circuit 223 so that a write driver operates, and the power signal and the bias signal or the like may be transmitted to the edge bit line EBL and thus to the write/read circuit 223.

When the memory device 100 includes multiple tiles, circuit regions of a unit (e.g., the write/read circuit 223 and the decoding circuits 222_1 and 222_2) illustrated in FIG. 11 may be disposed in the control layer (Layer 1) according to the tiles. Furthermore, although it is difficult to provide a line region for providing a signal from a circuit region corresponding to an external tile of a cell array to a circuit region corresponding to an internal tile in the control layer (Layer 1), as a power signal or a bias signal or the like is transmitted through the edge word line and/or the edge bit line according to some embodiments of the inventive concept, a signal may be easily provided to a circuit region corresponding to the internal tile.

Meanwhile, as illustrated in FIG. 11, bit lines that are used as normal bit lines may be separately disposed according to the respective tiles, whereas the edge bit line EBL may be disposed to pass the multiple tiles.

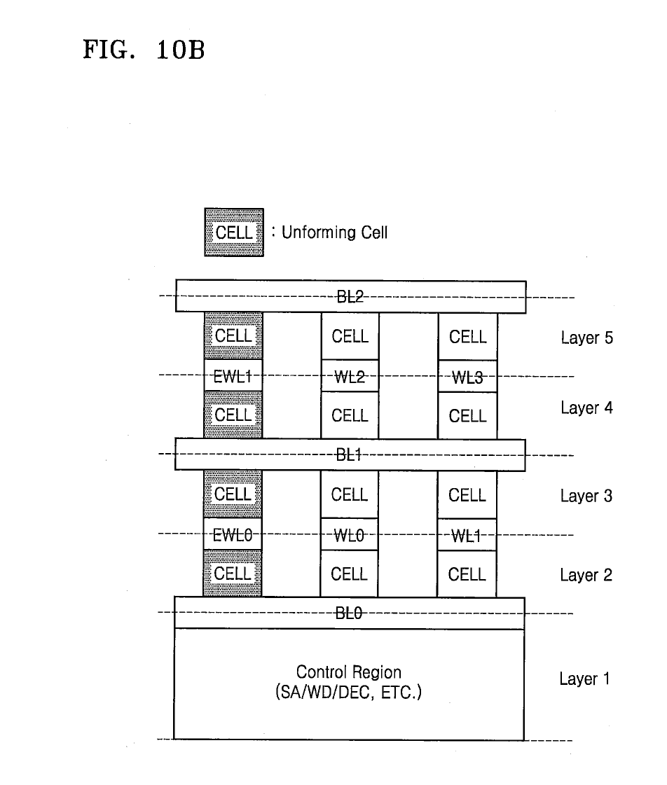

Referring now to FIGS. 12A and 12B, a signal transmission path of a control layer and a cell layer according to some embodiments of the present inventive concept will be discussed. As illustrated in FIG. 12A, at least one bit line is used as an edge bit line, and referring to FIG. 12B, at least one word line is used as an edge word line. Furthermore, the edge bit line is disposed parallel to a second direction, for example, a y-axis direction, in FIG. 12A, and the edge word line is disposed parallel to a first direction, for example, an x-axis direction, in FIG. 12B.

As illustrated in FIG. 12A, the control layer may include various circuits such as a power generating unit that generates power and multiple write/read circuits WD/SA1, WD/SA2, and WD/SA3. Furthermore, the cell layer may include multiple tiles Tile 1 through Tile 3 and at least one edge bit line, edge bit lines EBL1 and EBL2 disposed across the tiles Tile 1 through Tile 3. The power generating unit may generate various power signals such as a power voltage Vdd, a step-up voltage Vpp, and a ground voltage Vss and provide the same to the read/write circuits WD/SA1, WD/SA2, and WD/SA3. Furthermore, the power generating unit may generate a voltage such as a precharge voltage Vpre for precharging a bit line to a predetermined level to sense data, a reference voltage Vref to be compared with a voltage of a sensing node, and an inhibit voltage Vinh for biasing a line connected to non-selected memory cells, and provide the voltages to the write/read circuits WD/SA1, WD/SA2, and WD/SA3. A power signal and a voltage signal as described above are transmitted through edge bit lines EBL1 and EBL2, and may be provided to each of the write/read circuits WD/SA1, WD/SA2, and WD/SA3.

Meanwhile, as illustrated in FIG. 12B, the control layer may include various circuits such as a control logic that generates various control signals to control, for example, a memory operation, and multiple read/write circuits WD/SA1, WD/SA4, and WD/SA5. Furthermore, the cell layer may include multiple tiles Tile 1, Tile 4, and Tile 5, and at least one edge word line disposed across the tiles Tile 1, Tile 4, and Tile 5, In particular, edge word lines EWL1 and EWL2. The control logic may provide the write/read circuits with various control signals for a memory operation such as a precharge control signal PRE used to control a switch for precharging a bit line to a predetermined level, an enable control signal SAE used to control enabling of a sense amp that compares a voltage of a sensing node with a reference voltage, and a switch control signal CON_SW used to control various switches such as a clamping switch. Control signals such as the precharge control signal PRE, the enable control signal SAE, and the switch control signal CON_SW are transmitted via the edge word lines EWL1 and EWL2, and may be respectively provided to the write/read circuits WD/SA1, WD/SA4, and WD/SA5.

Referring to FIGS. 12A and 12B, while the edge word lines EWL1 and EWL2 and the edge bit lines EBL1 and EBL2 transmit different types of signals, the embodiments of the inventive concept are not limited thereto. For example, the various signals may be transmitted only through the multiple edge word lines EWL1 and EWL2 to be provided to the control layer, or the various signals may be transmitted only through the multiple edge bit lines EBL1 and EBL2 to be provided to the control layer. In some embodiments, the edge word lines EWL1 and EWL2 and the edge bit lines EWL1 and EWL2 may be disposed together, and the various signals may be provided to some tiles through the edge word lines EWL1 and EWL2, and to some other tiles through the edge bit lines EBL1 and EBL2.

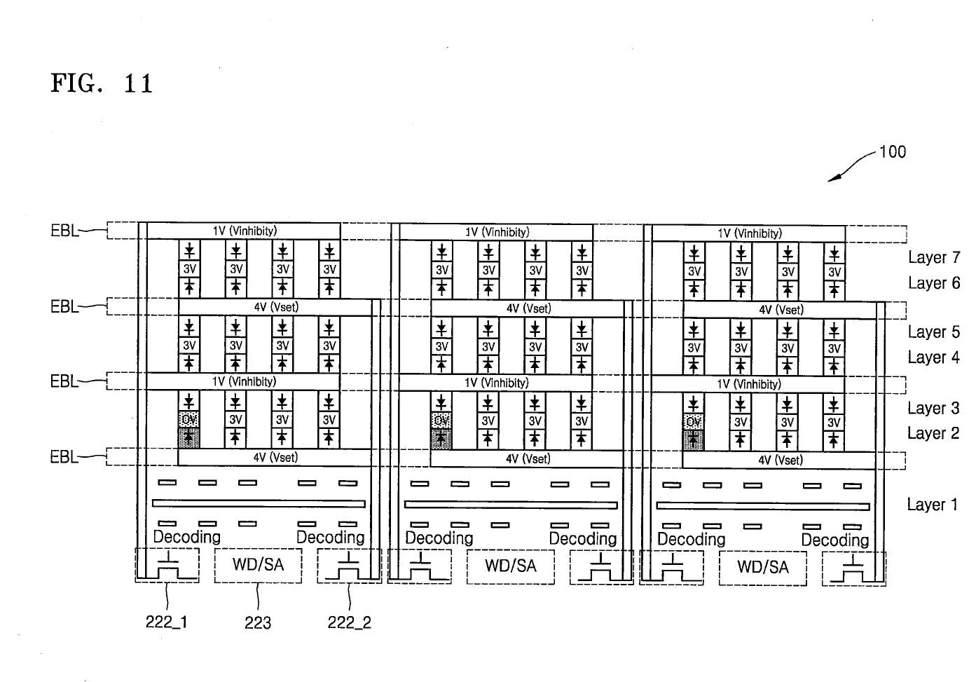

Referring now to FIG. 13, a memory device 300 according to some embodiments of the inventive concept will be discussed. Various signals used in a memory operation are transmitted not only through an edge word line (or an edge bit line) but additionally through an additional metal layer. As illustrated in FIG. 13, the memory device 300 includes multiple layers, and as a control layer is disposed on a substrate, a control region including various circuit regions may be formed in the control layer. Furthermore, a process of stacking a cell layer including a cell array on the control layer may be performed. For example, a metal layer including at least one metal line may be formed on the control layer, and a cell layer including a cell array may be stacked on the metal layer. The metal layer may also be defined as being included in the control layer.

According to some embodiments of the inventive concept, as some of multiple word lines (or multiple bit lines) included in tiles are used as an edge word line (or edge bit line) 310, the tiles may each include a first region 311 where memory cells which are actually accessed are disposed and a second region 312 where memory cells which are actually not accessed are disposed. According embodiments discussed above, the edge word line (or edge bit line) 310 may be disposed in the second region 312 of each of the tiles.

While various lines for controlling memory cells that are to be accessed are disposed at positions corresponding to the first region 311 in the metal layer, space where an additional line may be disposed may also be secured in the metal layer at a position corresponding to the second region 312. Accordingly, a metal line 320 may be disposed in the metal layer at a position corresponding to the second region 312, and the metal line 320 may be disposed parallel to the edge word line (or edge bit line) 310. Furthermore, the metal line 320 may be used as a line via which other various signals not related to access of memory cells are transmitted.

In particular, according to some embodiments, various signals such as the power signal or the bias signal may be provided to the tiles in the cell array by using the edge word line 310 (or the edge bit line 310) and the metal line 320. Furthermore, the various signals may be provided from the edge word line (or edge bit line) 310 and the metal line 320 to the control layer via at least one contact. Accordingly, when using the metal line 320 together, the number of the edge word lines 310 (or edge bit lines) 310 may be reduced, and consequently, the likelihood of an increase in sizes of the tiles may be reduced.

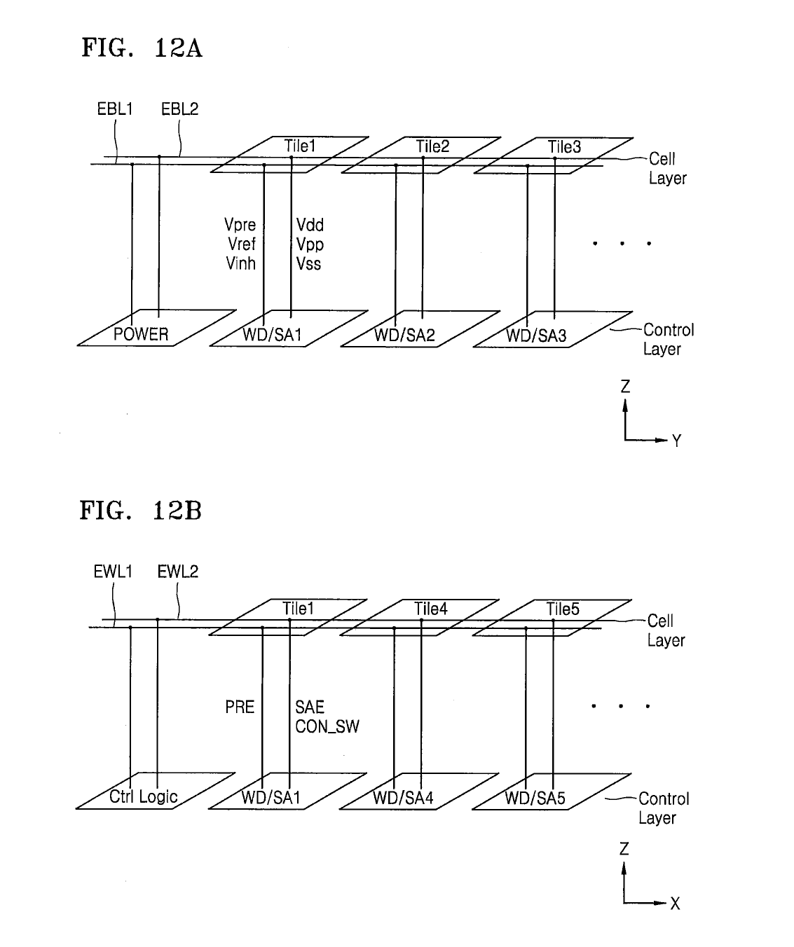

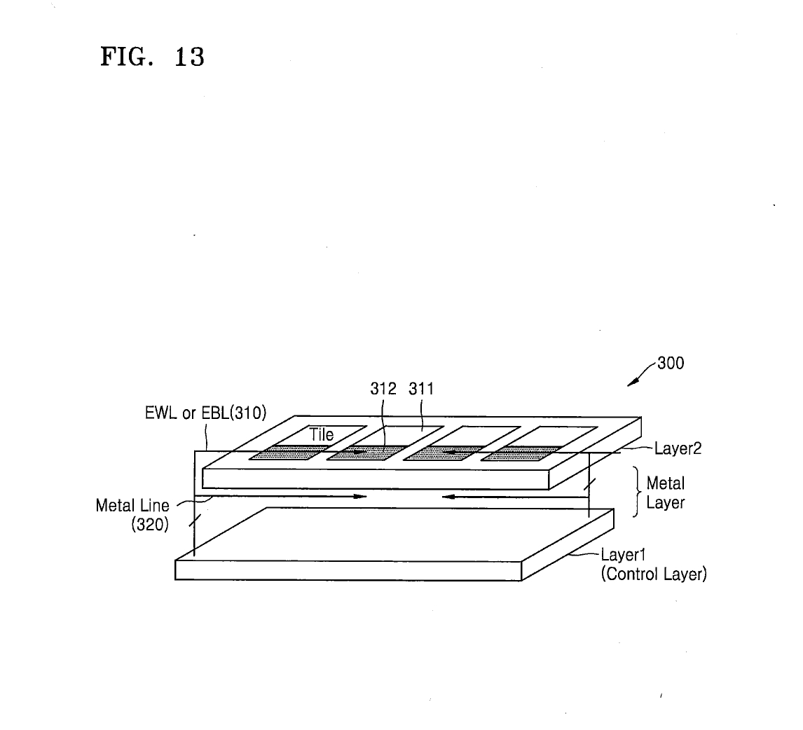

FIG. 14 is a plan view illustrating a line arrangement of a cell region according to some embodiments of the inventive concept. FIG. 15 is a diagram illustrating voltage signals provided to word lines of FIG. 14 according to some embodiments. FIG. 14 illustrates word lines and bit lines arranged in one cell layer, and a write/read circuit WD/SA may be disposed in a control layer under the cell layer. Furthermore, while some word lines are used as edge word lines EWL1 and EWL2 in FIG. 14, some bit lines may be further used as edge bit lines as described above.

As illustrated in FIG. 14, a cell array may include multiple tiles, and multiple word lines WL and multiple bit lines BL may be disposed in each tile. Furthermore, at least one edge word line. In particular, edge word lines EWL1 and EWL2, may be disposed parallel to a first direction of the cell layer, for example, a x-axis direction). If some bit lines are used as edge bit lines, the edge bit lines may be disposed parallel to a second direction of the cell layer, for example, a y-axis direction. According to some embodiments, various signals such as a power signal or a bias signal may be transmitted via the edge word lines EWl1 and EWL2, and a signal transmitted through the edge word lines EWL1 and EWL2 may be provided to the write/read circuit WD/SA of the control layer.

Meanwhile, according to some embodiments of the inventive concept, some of the multiple word lines WL may be used as dummy word lines DWL1 and DWL2. Accordingly, memory cells connected to the dummy word lines DWL1 and DWL2 may correspond to dummy cells, and a normal data access operation is not performed on the dummy cells. Compared to the dummy word lines DWL1 and DWL2, word lines WL connected to memory cells, on which normal data access is performed, may be referred to as normal word lines WL.

As a data access operation, as illustrated in FIG. 15, a select voltage Vwr is applied to a selected normal word line SWL in a data write operation and a data read operation, and an inhibit voltage Vinhx may be applied to other non-selected normal word lines UWL. Furthermore, an inhibit voltage Vinhx may be applied to the dummy word lines DWL1 and DWL2, and according to the above-described embodiment, the edge word lines EWL1 and EWL2 may be used as a signal line through which a power signal or a bias signal is transmitted.

According to some embodiments, the dummy word lines DWL1 and DWL2 may be disposed between the normal word lines WL and the edge word lines EWL1 and EWL1, and a normal data operation may be performed only on memory cells connected to the normal word lines WL. Although a difference in resistance level distributions may occur due to a difference in characteristics of memory cells disposed at an edge of a memory cell array and memory cells disposed in an inner portion of the memory cell array, as at least one word line disposed relatively at the edge is used as a dummy word line, data failure possibility may be reduced. Furthermore, an effect on the normal word lines connected to memory cells, where data is actually accessed, from the edge word lines EWL1 and EWL2, through which a voltage having a relatively high level, for example, a power voltage or a step-up voltage, is transmitted, may be reduced or possibly minimized.

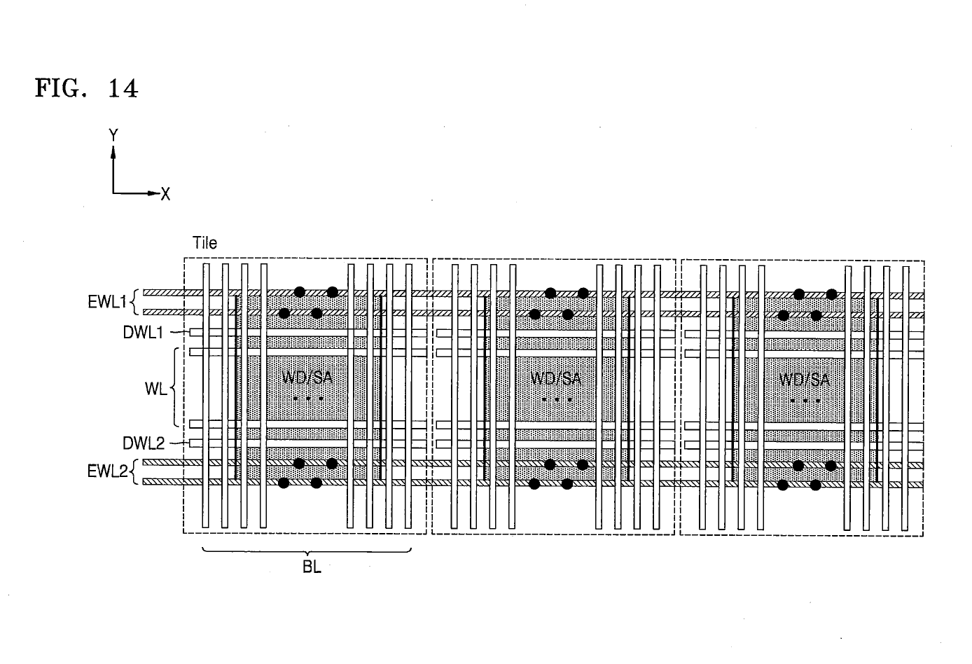

Referring now to FIG. 16, a block diagram of a memory device according to some embodiments of the inventive concept will be discussed. As illustrated in FIG. 16, each layer includes multiple tiles. A tile may include memory cells disposed in multiple layers. In particular, multiple layers may be divided into multiple cell regions; for example, first through sixth tiles Tile 1 through Tile 6 may be included in the multiple layers.

A control layer disposed in a lower portion may include multiple circuit regions, and circuit regions in the control layer may transmit or receive a signal to and from one another via an edge word line (and/or edge bit line) disposed in the cell layer. Multiple cell layers may be stacked on the control layer, and an edge word line (and/or an edge bit line) may be disposed in at least some of the multiple cell layers.

According to some embodiments, as illustrated in FIG. 16, while some cell layers of the memory device include an edge word line and/or an edge bit line, some other cell layers may not include an edge word line or an edge bit line. For example, a cell layer that is stacked adjacent to the control layer, for example, a second layer (Layer 2), may include an edge word line and/or an edge bit line, and a cell layer that is relatively away from the control layer, for example, an Ath layer (Layer A), may not include an edge word line or an edge bit line.

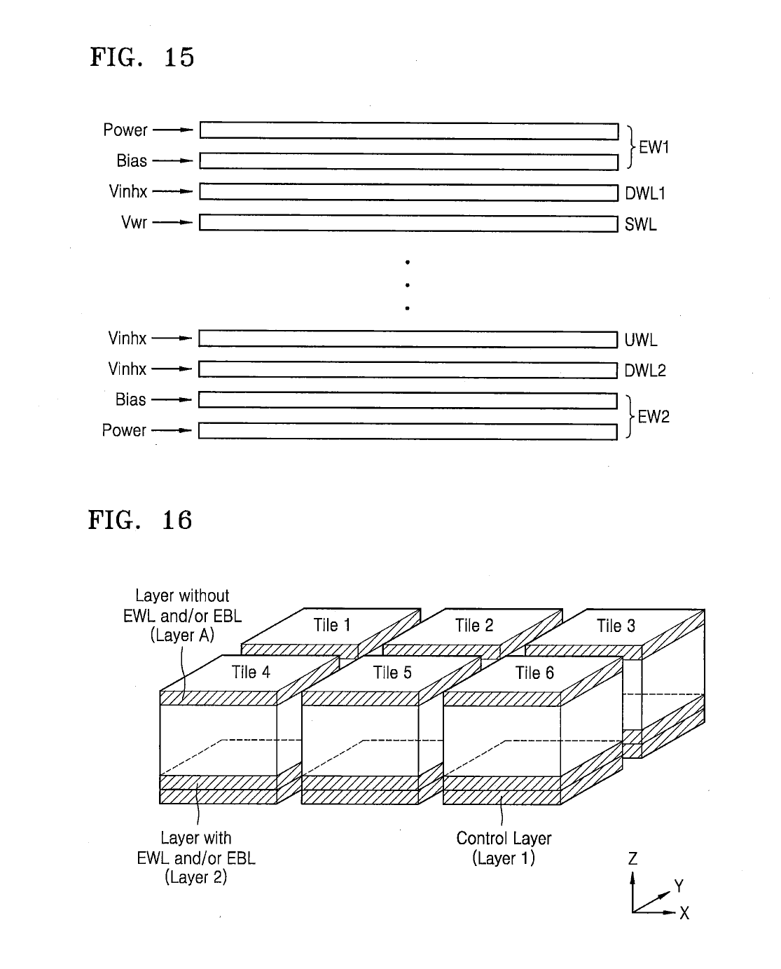

Referring now to FIG. 17, a block diagram of a memory card system 400 having a memory system applied thereto, according to some embodiments of the inventive concept will be discussed. As illustrated in FIG. 17, the memory card system 400 may include a host 410 and a memory card 420. The host 410 may include a host controller 411 and a host connector 412. The memory card 420 may include a card connector 421, a card controller 422, and a memory device 423. In these embodiments, the memory device 423 may be embodied by using the embodiments shown in FIGS. 1 through 16, and according to some embodiments, the memory device 423 may include resistive memory cells.

The memory device 423 may include multiple layers including a control layer and a cell layer, and an edge word line and/or an edge bit line through which various signals such as a power signal or a bias signal are transmitted from the control layer may be disposed in at least some cell layers. Furthermore, according to some embodiments discussed above, various signals such as a power signal or a bias signal generated in a circuit region of the control layer may be provided to another circuit region of the control layer via the edge word line and/or the edge bit line.

The host 410 may write data to the memory card 420 or may read data stored in the memory card 420. The host controller 411 may transmit a command CMD, a clock signal CLK generated by a clock generator (not shown) in the host 410, and data DATA to the memory card 420 via the host connector 412.

In response to the command CMD received via the card connector 421, the card controller 422 may store the data DATA in the memory device 423, in synchronization with a clock signal that is generated by a clock generator in the card controller 422. The memory device 423 may store the data DATA that is transmitted from the host 410.

The memory card 420 may be embodied as, for example, a Compact Flash Card (CFC), a Microdrive, a Smart Media Card (SMC), an Multimedia Card (MMC), a Security Digital Card (SDC), a memory stick, or a Universal Serial Bus (USB) flash memory drive.

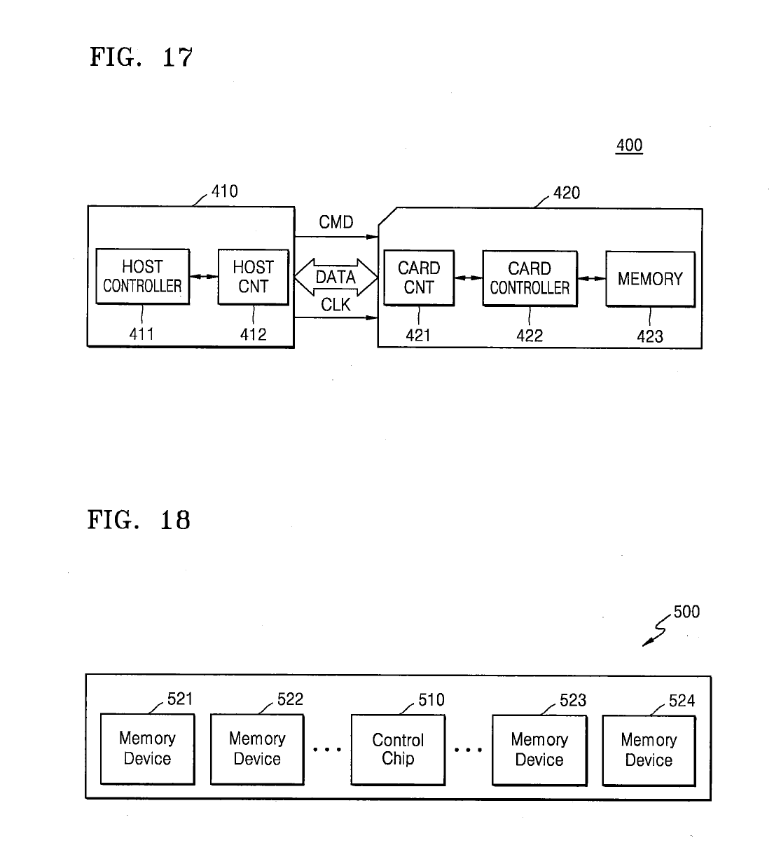

Referring now to FIG. 18, a memory module 500 according to some embodiments of the inventive concept will be discussed. As illustrated in FIG. 18, the memory module 500 may include memory devices 521 through 524, and a control chip 510. Each of the memory devices 521 through 524 may be embodied by using the embodiments shown in FIGS. 1 through 16. In response to various signals transmitted by an external memory controller, the control chip 510 may control the memory devices 521 through 524. For example, according to various commands and addresses that are transmitted from an external source, the control chip 510 may activate the memory devices 521 through 524 corresponding to the various commands and addresses and thus may control write and read operations. Furthermore, the control chip 510 may perform various post processing operations on read data output from each of the memory devices 521 through 524, for example, the control chip 510 may perform error detection and correction operations on the read data.

According to some embodiments, the memory devices 521 through 524 may each include multiple layers including a control layer and a cell layer, and an edge word line and/or an edge bit line through which various signals such as a power signal or a bias signal from the control layer is transmitted may be disposed in some cell layers. Furthermore, according to the above-described embodiment, various signals such as a power signal or a bias signal generated in a circuit region of the control layer may be provided to another circuit region of the control layer via the edge word line and/or the edge bit line.

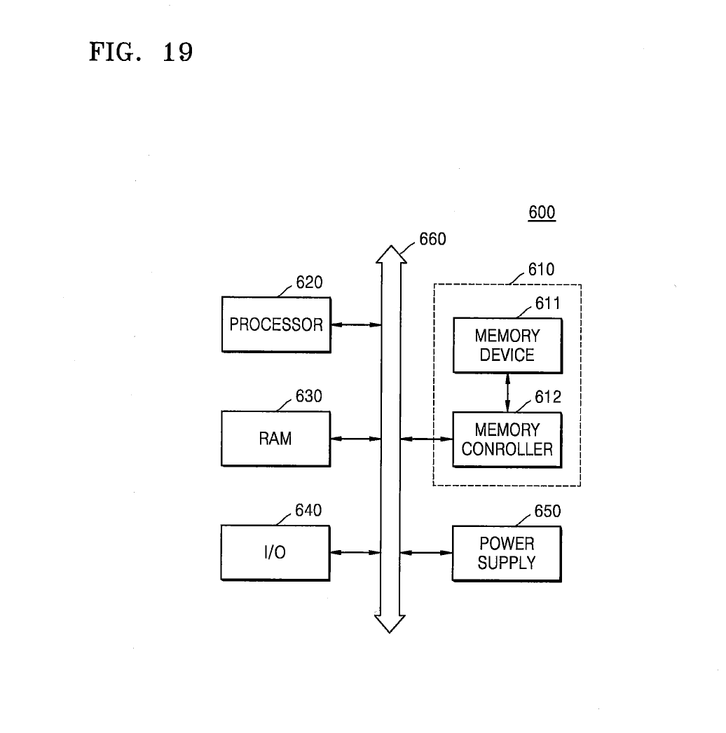

Referring now to FIG. 19, a block diagram of a computing system 600 including a memory system according to some embodiments of the inventive concept will be discussed. As illustrated in FIG. 19, the computing system 600 may include a memory system 610, a processor 620, a RAM 630, an input/output (I/O) device 640, and a power supply device 650. The memory system 610 may include a memory device 611 and a memory controller 612. Although not illustrated in FIG. 19, the computing system 600 may further include ports capable of communicating with a video card, a sound card, a memory card, or a USB device, or other electronic devices. The computing system 600 may be embodied as a PC, or a portable electronic device such as a notebook computer, a mobile phone, a personal digital assistant (PDA), or a camera.

The processor 620 may perform particular calculations or tasks. In one or more embodiments, the processor 620 may be a micro-processor, a Central Processing Unit (CPU), or the like. The processor 620 may perform communication with the RAM 630, the I/O device 640, and the memory system 610 via a bus 660 such as an address bus, a control bus, or a data bus. In these embodiments, the memory system 610 and/or the RAM 630 may be embodied by using the embodiments shown in FIGS. 1 through 16.

In one or more embodiments, the processor 620 may also be connected to an extended bus such as a Peripheral Component Interconnect (PCI) bus.

The RAM 630 may store data for operations of the computing system 600. As described above, the memory device according to the one or more embodiments of the inventive concept may be applied to the RAM 630. Alternatively, a DRAM, a mobile DRAM, an SRAM, a PRAM, an FRAM, or an MRAM may be used as the RAM 630.

The I/O device 640 may include an input unit such as a keyboard, a keypad, or a mouse, and an output unit such as a printer or a display. The power supply device 650 may supply an operating voltage for the operations of the computing system 600.

While the inventive concept has been particularly shown and described with reference to exemplary embodiments thereof, it will be understood that various changes in form and details may be made therein without departing from the spirit and scope of the following claims.

What is claimed is:

1. A memory device comprising:
a cell region comprising at least one cell layer, wherein each of the at least one cell layers comprises multiple first lines and multiple second lines, different from the first lines; and
a control region comprising at least one control layer, wherein the at least one control layer comprises multiple circuit regions for performing a memory operation on the cell region,
wherein the multiple first lines comprise at least one first signal line through which a first signal from a first circuit region of the control layer is transmitted to a second circuit region, different from the first circuit region, of the control layer.

2. The memory device of claim 1, wherein the at least one first signal line is at least one edge line disposed at an edge of the memory device from among the multiple first lines.

3. The memory device of claim 1, wherein access to a memory cell connected to the at least one first signal line is prohibited.

4. The memory device of claim 3, wherein a memory cell connected to the at least one first signal line is formed by skipping an operation of forming at least one of a variable resistor device and a selection device.

5. The memory device of claim 3, wherein a memory cell connected to the at least one first signal line is formed by skipping performing a forming operation.

6. The memory device of claim 1, wherein at least one of a power signal and a bias signal generated in the first circuit region is transmitted via the at least one first signal line.

7. The memory device of claim 6:
wherein the first circuit region comprises a power generating unit; and
wherein the second circuit region comprises a write/read circuit.

8. The memory device of claim 1, wherein the multiple second lines include at least one second signal line through which a second signal from a third circuit region of the control layer is transmitted to a fourth circuit region, different from the third circuit region, of the control layer.

9. The memory device of claim 1:
wherein the cell layer comprises a tile group including multiple tiles; and
wherein the first signal is transmitted through the at least one first signal line from a position corresponding to outside of the tile group to a position corresponding to a tile in the tile group.

10. A memory device comprising:
a first layer comprising multiple memory cells, multiple first lines connected to accessible memory cells, and at least one signal line that is connected to access-inhibited memory cells and disposed parallel to the first lines; and
a second layer through which, in a memory operation, at least one of a power signal and a bias signal that are not related to a selection operation performed on the memory cells is provided to the at least one signal line.

11. The memory device of claim 10:
wherein the at least one signal line is connected to a first end of the access-inhibited memory cells;
wherein the first layer further comprises a second line connected to a second end of the access-inhibited memory cells; and
wherein the at least one signal line and the second line are physically or electrically separated from each other.

12. The memory device of claim 10, wherein the second layer comprises:
a power generating unit that generates at least one of the power signal and the bias signal; and
a write/read circuit that is electrically connected to the at least one signal line and receives at least one of the power signal and the bias signal.

13. The memory device of claim 10:
wherein the first layer further comprises at least one dummy line disposed between the first lines and the at least one signal line; and
wherein the at least one dummy line is connected to dummy cells.

14. The memory device of claim 10, wherein the first layer comprises multiple tiles, and the first lines are separately disposed according to the multiple tiles, and the at least one signal line is commonly disposed with respect to the multiple tiles.

15. The memory device of claim 10, further comprising:
a first group signal lines through which at least one of the power signal and the bias signal is provided to a signal line of the first layer; and
a second group signal lines through which at least one of the power signal and the bias signal that are transmitted via the at least one signal line of the first layer is provided to the second layer.

16. A memory device comprising:
a plurality of word lines and bit lines, the plurality of word lines being relatively perpendicular to the plurality of bit lines; and
a plurality of memory cells coupled to the plurality of word lines, wherein at least one of the plurality of words lines is positioned at an edge of the memory device and wherein a memory cell associated with the at least one word line positioned at an edge of the memory device is not used,
wherein the at least one word line positioned at an edge of the memory device is configured to transmit at least one of a power signal and a bias signal.

17. The memory device of claim 16, wherein the at least one power signal and/or bias signal is transmitted via the at least one word line positioned at the edge of the memory device through an entire cell layer.

18. The memory device of claim 16, further comprising at least one contact, wherein the word line positioned at the edge of the memory device is connected to a control layer via the at least one contact.

19. The memory device of claim 18, wherein a signal generated in a circuit of the control layer is transmitted via the word line positioned at an edge of the memory device and provided to other circuits of the control layer from a node of the word line positioned at the edge of the memory device.

20. The memory device of claim 16, further comprising a power generating unit that generates at least one of the power signal and the bias signal.
